(19) United States
(12) Patent Application Publication
(10) Pub. No.: US 2007/0155127 A1
(43) Pub. Date: Jul. 5, 2007

(54) Image sensor and method of fabricating the same

(75) Inventor: Joo Hyun Lee, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/643,910

(22) Filed: Dec. 22, 2006

(30) Foreign Application Priority Data
Dec. 29, 2005 (KR) 10-2005-0133181

(51) Int. Cl. H01L 21/76

(52) U.S. Cl. 438/424

(57) ABSTRACT

The image sensor includes a substrate, having a photodiode region and a device separation region; a trench formed in the device separation region; and a nitride film formed on the inner surface of the trench. The nitride film may comprise one formed using a gas selected from among N₂, NO, and NO₂. The nitride film may further include Ar.

### FIELD OF THE INVENTION

The present invention relates to a method of fabricating an image sensor, and more particularly, to an image sensor which is capable of preventing diffusion of ions from a doped region to the inside of a trench, and to a method of fabricating the same.

### BACKGROUND OF THE INVENTION

Generally, a CMOS (Complementary Metal Oxide Semiconductor) image sensor is a semiconductor device for converting optical images into electrical signals, and is composed of a photo-sensing unit for sensing light and a logic circuit unit for processing the sensed light into electrical signals to convert them to data. Further, the CMOS image sensor adopts a switching methodology by which the same number of MOST transistors as the number of pixels are provided using CMOS technology to thereby enable the detection of outputs on a one-by-one basis.

FIG. 1 is a cross sectional view of a conventional image sensor.

As illustrated in FIG. 1, the conventional image sensor comprises a substrate 100 having a device separation region and a photodiode region, along with a trench 101 formed in the device separation region of the substrate 100.

Further, in the photodiode region, a doped region 103 (a well region) is formed. Also, a channel stop region 104 is formed along the inner shape of the trench 101 in the device separation region in order to enclose the inner surface of the trench 101 therewith.

The channel stop region 104 functions as a diffusion barrier for preventing the ions, which are implanted into the doped region, from diffusing to the trench 101.

The process of forming such a channel stop region 104 is as follows.

First, a photoresist pattern is formed to mask a portion of the substrate other than the inner surface of the trench 101. Using the photoresist pattern as a mask, boron is injected into the inner surface of the exposed trench 101, thus forming the channel stop region 104.

Thereafter, an ashing process is performed to remove the photoresist pattern, and a cleaning process is used to remove the residue of the photoresist pattern.

In this way, the channel stop region 104 is formed.

Further, a device separation film is formed in the trench 101, and the substrate 100 is annealed to alleviate the stress of the device separation film.

However, the conventional image sensor has the following problems.

First, a large number of processes are required for forming the stop channel region.

In addition, boron ions may be diffused from the channel stop region 104 to the doped region due to the high temperature that is applied to the substrate 100 in the annealing process.

### SUMMARY OF THE INVENTION

Therefore, the present invention has been made keeping in mind the above problems occurring in the prior art, and is directed to providing an image sensor, in which a nitride film is formed on the inner surface of a trench to thus easily isolate the trench from a doped region, and a method of fabricating the same.

In order to accomplish the above, an embodiment of the present invention provides an image sensor, comprising a substrate, having a photodiode region and a device separation region; a trench formed in the device separation region; and a nitride film formed on the inner surface of the trench.

The nitride film may comprise one formed using any one of the gases selected from among N₂, NO, and NO₂.

The nitride film may further include Ar.

In addition, an embodiment of the present invention provides a method of fabricating an image sensor, comprising preparing a substrate having a photodiode region and a device separation region; forming a trench in the device separation region; forming an oxide film over the entire surface of the substrate having the trench; and injecting a nitride forming gas into the oxide film.

The nitride gas may be any one selected from among N₂, NO, and NO₂ gases.

The method may further comprise injecting an Ar gas into the oxide film.

Also, the method may further comprise forming an insulating film over the entire surface of the substrate to fill the inside of the trench; planarizing the insulating film and the oxide film to form a device separation film embedded in the trench; annealing the substrate; and forming a well in the photodiode region.

### BRIEF DESCRIPTION OF THE DRAWINGS

The above and other features of the present invention will become apparent from the following description of preferred embodiments given in conjunction with the accompanying drawings, in which:

FIG. 1 is a cross sectional view of a conventional image sensor;

FIG. 2 is a cross sectional view of the image sensor according to an embodiment of the present invention; and

FIGS. 3A to 3F are cross sectional views depicting the process of fabricating an image sensor, according to another embodiment of the present invention.

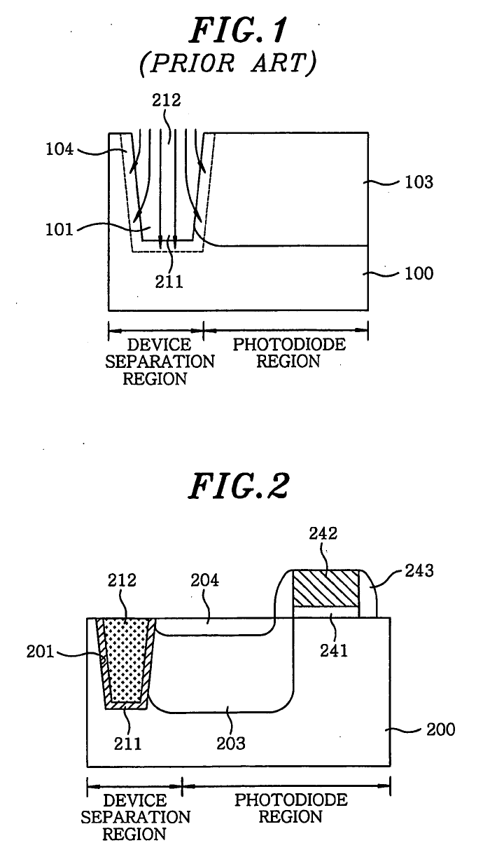

### DETAILED DESCRIPTION OF THE EXEMPLARY EMBODIMENTS

Exemplary embodiments of the present invention will now be described in detail with reference to the accompanying drawings.

FIG. 2 is a cross sectional view of an image sensor according to the present invention.

As illustrated in FIG. 2, the image sensor according to an embodiment of the present invention comprises a substrate 200 having a device separation region and a photodiode region, a trench 201 formed in the device separation region, first and second doped regions 203, 204 formed in the photodiode region, a gate insulating film 241 formed in the photodiode region, a gate electrode 242 formed on the gate insulating film 241, spacers 243 formed on both side surfaces of the gate electrode 242 and the gate insulating film 241, a nitride film 211 formed on the inner surface of the trench 201 for preventing diffusion from the first and second doped regions 203, 204 to the inside of the trench 201, and a device separation film 212 embedded in the trench 201.

The nitride film 211 comprises one formed using any gas selected from among N₂, NO, and NO₂. That is, the nitride film 211 may be formed on the inner surface of the trench 201 through plasma deposition using any gas selected from among N₂, NO, and NO₂.

Further, among the above listed gases, any one may be mixed with Ar gas, and thus be applied on the inner surface of the trench 201 through plasma deposition.

The nitride film 211 thus formed, functions as a diffusion barrier for preventing diffusion of the dopant from the first and second doped regions 203, 204 to the trench 201.

Hereinafter, the method of fabricating the image sensor according to an embodiment of the present invention will be described in detail.

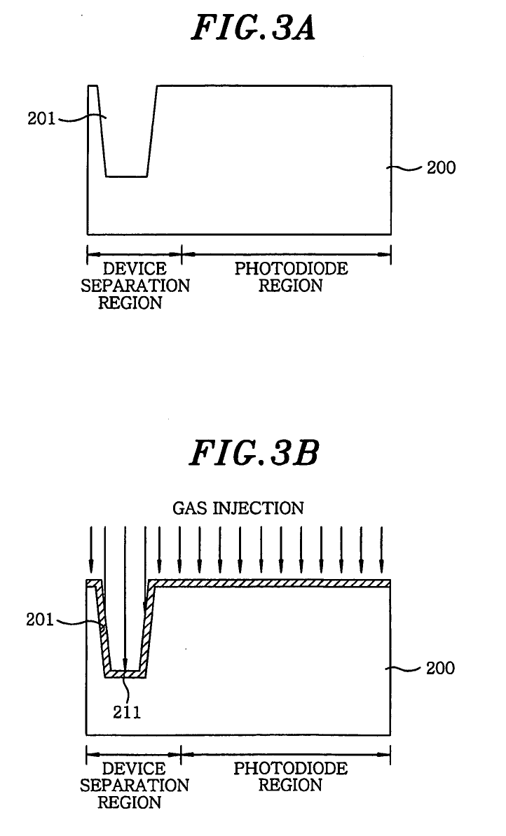

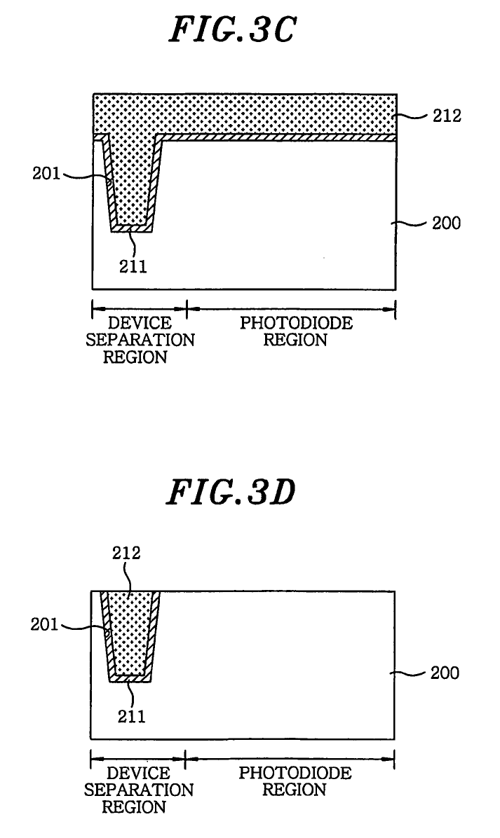

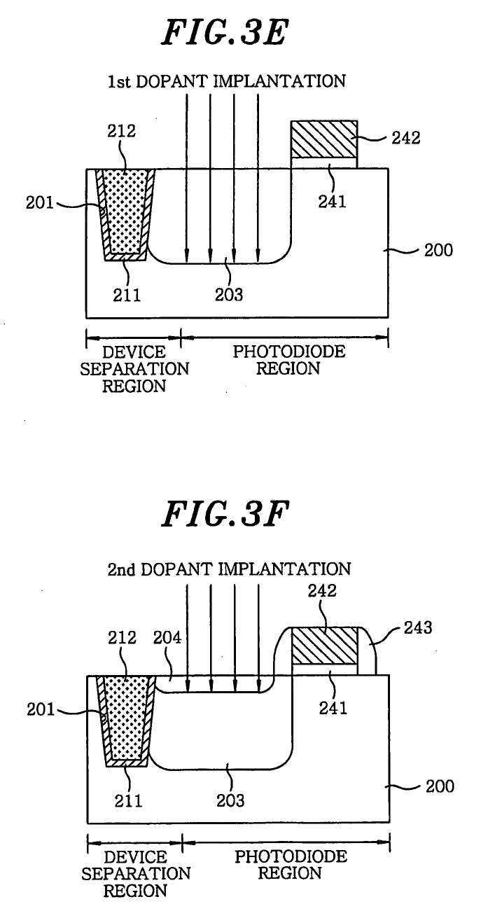

FIGS. 3A to 3F are cross sectional views depicting the process of fabricating the image sensor, according to an embodiment of the present invention.

As illustrated in FIG. 3A, a substrate 200 having a device separation region and a photodiode region is prepared. A trench 201 is formed to a predetermined depth in the device separation region through a photo process and an etching process.

In this emboidment, the substrate 200 may be a P-type semiconductor substrate 200 having a P-epi layer or an N-type semiconductor substrate 200 having an N-epi layer.

Thereafter, as illustrated in FIG. 3B, a film 211 (an oxide film) is deposited over the entire surface of the substrate 200 having the trench 201. Subsequently, any gas selected from among N₂, NO and NO₂ is injected into the oxide film 211 so that the oxide film is converted into a nitride film 211 by the gas.

Further, in addition to N₂, NO and NO₂ gases, any one may be injected along with Ar gas into the film.

In such a case, the N₂ gas is supplied into the chamber in which the substrate 200 is loaded, under the condition of a temperature of about 500° C., pressure of 300 Pa and a flow rate of about 2 SLM for about 1 min.

In addition, the Ar gas is supplied into the chamber in which the substrate 200 is loaded, under the condition of a temperature of about 500° C., pressure of 300 Pa and a flow rate of about 1 SLM for about 1 min.

In addition, the NO or N₂O gas is supplied into the chamber in which the substrate 200 is loaded, under the condition of a temperature of about 900° C., pressure of 500 Torr and a flow rate of about 2 SLM for about 2 hours.

Subsequently, as illustrated in FIG. 3C, a device separation film 212 is deposited over the entire surface of the substrate 200 to be embedded in the trench 201. Further, the device separation film 212 and the nitride film 211 are simultaneously planarized through CMP (Chemical Mechanical Polishing).

As illustrated in FIG. 3D, the nitride film 211 is thus formed on the inner surface of the trench 201, and the device separation film 212 is embedded in the trench 201. Accordingly, the substrate 200 has a field oxide film having a structure of STI (Shallow Trench Insulator).

Thereafter, as illustrated in FIG. 3E, the photodiode region is subjected to a photo process and an etching process to thus sequentially form a gate insulating film 241 and a gate electrode 242.

Thereafter, a first dopant is selectively implanted into the photodiode region, thus forming a first doped region 203.

In this case, due to the nitride film 211, the first dopant does not diffuse to the inside of the trench 201.

Subsequently, as illustrated in FIG. 3F, spacers 243 are formed on both side surfaces of the gate electrode 242, after which a second dopant is implanted into the photodiode region, thereby forming a second doped region 204.

Thereafter, the substrate 200 is annealed to alleviate the stress of the device separation film 212 formed in the trench 201.

At that time, since the N₂, NO, or NO₂ contained in the nitride film 211 has lower diffusibility than boron, which is conventionally used, the substrate 200 may be annealed at a high temperature for a sufficient period of time.

As described hereinbefore, the present invention provides an image sensor and a method of fabricating the same. According to the present invention, a nitride film is formed on the inner surface of a trench, such that ions may be prevented from diffusing from the doped region to the inside of the trench.

Further, the present invention does not require processes required for forming a channel stop region, including the application of a photoresist pattern, development, ashing, and washing, resulting in increased process efficiency.

While the invention has been shown and described with reference to a limited number of embodiments, it will be understood by those skilled in the art that various changes and modifications may be made without departing from the spirit and scope of the invention as defined in the following claims.

What is claimed is:

1. An image sensor, comprising:
a substrate, having a photodiode region and a device separation region;
a trench formed in the device separation region; and
a nitride film formed on an inner surface of the trench.

2. The image sensor of claim 1, wherein the nitride film comprises one formed using a gas selected from among N₂, NO, and NO₂.

3. The image sensor of claim 1, wherein the nitride film further comprises Ar.

4. A method of fabricating an image sensor, comprising:
preparing a substrate having a photodiode region and a device separation region;
forming a trench in the device separation region;
forming an oxide film over an entire surface of the substrate having the trench; and
injecting a nitride forming gas into the oxide film.

5. The method of claim 4, wherein the nitride gas is any one selected from among N₂, NO, and NO₂.

6. The method of claim 4, further comprising injecting Ar gas into the oxide film.

7. The method of claim 4, further comprising:
forming an insulating film over the entire surface of the substrate to fill an inside of the trench;
planarizing the insulating film and the oxide film to form a device separation film embedded in the trench;
annealing the substrate; and
forming a well in the photodiode region.
